(19) United States
(12) Patent Application Publication
(10) Pub. No.: US 2025/0318153 A1
(43) Pub. Date: Oct. 9, 2025

(54) CAPACITOR WITH CONTACT STRUCTURES FOR CAPACITANCE DENSITY BOOST

(71) Applicant: Taiwan Semiconductor Manufacturing Company, Ltd., Hsinchu (TW)

(72) Inventors: Yi-Chen Chen, Jhubei City (TW); Ming Chyi Liu, Hsinchu City (TW)

(21) Appl. No.: 19/243,043

(22) Filed: Jun. 19, 2025

Related U.S. Application Data
(62) Division of application No. 17/697,197, filed on Mar. 17, 2022.

(51) Int. Cl. H10D 1/00; H01L 21/768; H01L 23/522; H10D 1/68

(52) U.S. Cl. CPC H10D 1/042; H01L 21/76832; H01L 23/5226; H10D 1/043; H10D 1/716

(57) ABSTRACT

Various embodiments of the present disclosure are directed towards an integrated circuit (IC) including a capacitor. The capacitor is disposed over a semiconductor substrate. The capacitor includes a plurality of electrodes and a plurality of capacitor dielectric layers vertically stacked over one another. A contact structure overlies the plurality of electrodes, wherein the contact structure continuously extends from above a top surface of the plurality of electrodes to contact a first electrode in the plurality of electrodes. A first conductive via overlies and contacts the contact structure, wherein the first conductive via is directly electrically coupled to the first electrode by way of the contact structure.

### REFERENCE TO RELATED APPLICATION

This Application is a Divisional of U.S. application Ser. No. 17/697,197, filed on Mar. 17, 2022, the contents of which are hereby incorporated by reference in their entirety.

### BACKGROUND

A trench capacitor exhibits high power density relative to some other capacitor types within a semiconductor integrated circuit (IC). As such, trench capacitors are utilized in applications such as dynamic random-access memory (DRAM) storage cells, among other applications. Some examples of trench capacitors include high density deep trench capacitors (DTCs) which are utilized in advanced technology node processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of some embodiments of an integrated circuit (IC) including a capacitor having one or more contact structures.

FIG. 1B illustrates a top view of various embodiments of the capacitor of FIG. 1A.

FIGS. 2A-2D illustrate various views of some embodiments of an IC including a capacitor having a plurality of contact structures.

FIGS. 3A-3D illustrate various views of some embodiments of an IC according to some alternative embodiments of the IC of FIGS. 2A-2D.

FIGS. 4A-4D illustrate various views of some embodiments of an IC including a capacitor having a plurality of contact structures.

FIGS. 5, 6, and 7A-7C through 14A-14C illustrate various cross-sectional views of some embodiments of a method for forming an IC including a capacitor having a plurality of contact structures.

FIG. 15 illustrates a flowchart of some embodiments of a method for forming an IC including a capacitor having a plurality of contact structures.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits (ICs) may include a number of semiconductor devices such as a trench capacitor disposed within and/or over a semiconductor substrate. The semiconductor substrate may comprise sidewalls that define one or more trenches. The trench capacitor includes multiple electrodes and one or more dielectric layers, where the multiple electrodes and the dielectric layer(s) are alternatively stacked in the one or more trenches. One or more conductive vias overlies and contacts each electrode. The multiple electrodes may be electrically coupled in a predefined manner by way of the conductive vias and one or more conductive wires.

In an effort to increase the capacitance density of the trench capacitor, the number of electrodes disposed within the one or more trenches may be increased. However, as the number of electrodes increases, the number of conductive vias contacting the trench capacitor increases accordingly. Further, one or more of the electrodes have a contact region that is laterally offset from the one or more trenches by a non-zero distance, where conductive vias directly contact the respective electrode in the corresponding contact region. Each contact region may have a relatively large footprint in order to prevent issues (e.g., misalignment between conductive vias and corresponding electrodes, electrodes being shorted together, etc.) during fabrication as a result of processing tool limitations (e.g., an overlay shift or over etching during fabrication of the conductive vias in each contact region). This results in an increase of a minimum footprint of the trench capacitor to accommodate the conductive vias disposed over each electrode (e.g., a minimum width and length of the trench capacitor is greater than 4 micrometers), thereby decreasing a number of trench capacitors that may be disposed on/over a single semiconductor substrate (e.g., decreases device density).

Accordingly, various embodiments of the present application are directed towards an integrated circuit (IC) comprising a trench capacitor that has one or more contact structures configured to decrease a lateral footprint of the trench capacitor. In some embodiments, the trench capacitor comprises a plurality of electrodes and a plurality of capacitor dielectric layers that respectively line a trench of a semiconductor substrate. Further, a contact structure directly overlies at least a portion of the trench and continuously extends from above a top surface of the plurality of electrodes to contact a first electrode in the plurality of electrodes. The contact structure is configured as a contact region for the first electrode such that a first conductive via is disposed on the contact structure and is directly electrically coupled to the first electrode by way of the contact structure. By virtue of the contact structure at least partially overlying the trench, a minimum width and length of the trench capacitor may be reduced while ensuring the contact structure is sufficiently large to facilitate proper landing of the first conductive via on the contact structure. This mitigates issues during fabrication of the trench capacitor as a result of processing tool limitations while increasing a number of semiconductor devices (e.g., trench capacitors) that may be disposed on/over the semiconductor substrate. Thus, a performance (e.g., capacitance density) of the trench capacitor may be maintained while increasing a device density of the IC.

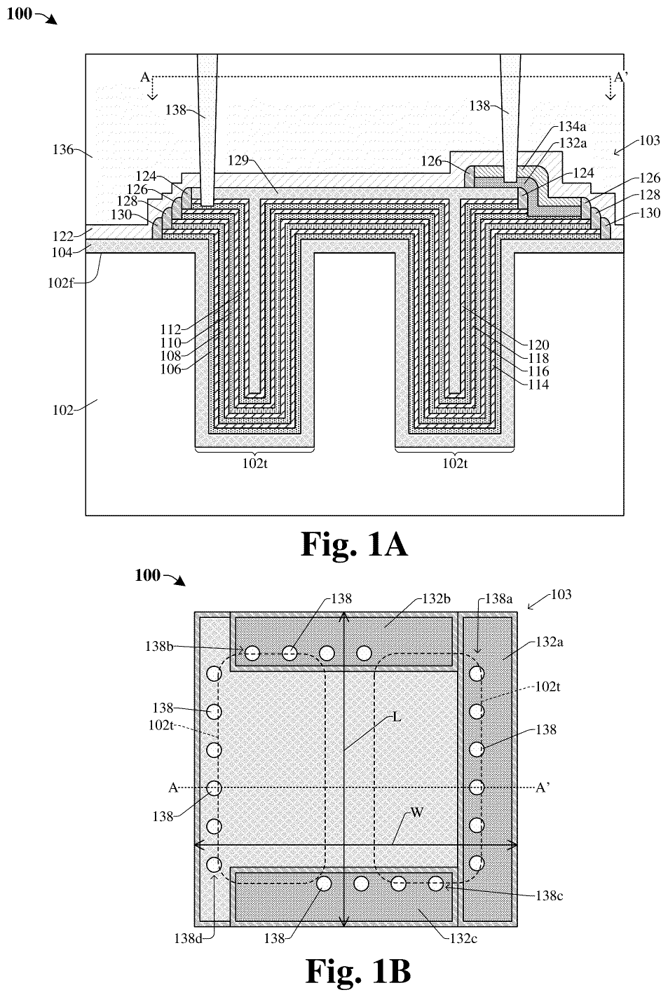

FIG. 1A illustrates a cross-sectional view of some embodiments of an integrated circuit (IC) 100 having a capacitor 103 disposed within a semiconductor substrate 102.

The semiconductor substrate 102 comprises a plurality of sidewalls that define a plurality of trenches 102t extending into a front-side surface 102f of the semiconductor substrate 102. The capacitor 103 overlies the front-side surface 102f of the semiconductor substrate 102 and comprises a plurality of trench segments that fill the plurality of trenches 102t. An insulator layer 104 extends along a front-side surface 102f of the semiconductor substrate 102 and along the sidewalls of the semiconductor substrate 102 that define the plurality of trenches 102t. An etch stop layer 122 overlies the capacitor 103 and the semiconductor substrate 102. An interlayer dielectric (ILD) layer 136 overlies the etch stop layer 122. A plurality of conductive vias 138 is disposed within the ILD layer 136 and electrically coupled to the capacitor 103. In some embodiments, the capacitor 103 may be configured as a trench capacitor, a planar capacitor, a cylinder capacitor, a bar capacitor, a dual-damascene capacitor, or the like.

In some embodiments, the capacitor 103 comprises a plurality of electrodes 106-112 and a plurality of capacitor dielectric layers 114-120 alternatingly disposed between the electrodes 106-112. The plurality of electrodes 106-112 include a first electrode 106, a second electrode 108, a third electrode 110, and a fourth electrode 112. The plurality of capacitor dielectric layers 114-120 includes a first capacitor dielectric layer 114, a second capacitor dielectric layer 116, a third capacitor dielectric layer 118, and a fourth capacitor dielectric layer 120. In various embodiments, a capacitance density of the capacitor 103 may be increased by increasing an area of overlap between adjacent electrodes in the plurality of electrodes 106-112. The capacitance density of the capacitor 103 may be further increased by increasing a number of trenches 102t in which the capacitor 103 is disposed in. In yet further embodiments, the first and third electrodes 106, 110 may be electrically coupled together by way of the plurality of conductive vias 138 and conducive wires (not shown) to define a first plate of the capacitor 103 and the second and fourth electrodes 108, 112 may be electrically coupled together by way of the plurality of conductive vias 138 and conductive wires (not shown) to define a second plate of the capacitor 103. A capping dielectric layer 129 overlies the capacitor 103 and extends into the plurality of trenches 102t. Further, a plurality of sidewall spacers 124-130 laterally enclose sidewalls of the plurality of electrodes 106-112.

A first contact structure 132a overlies the capping dielectric layer 129 and continuously extends from over the capping dielectric layer 129 to contact an upper surface of the third electrode 110. A first masking layer 134a overlies the first contact structure 132a. The first contact structure 132a comprises a conductive material (e.g., a metal such as titanium, titanium nitride, tantalum, tantalum nitride, tungsten, aluminum copper, etc.) and is configured to directly electrically couple the third electrode 110 to an overlying conductive contact 138. In some embodiments, an inner region of the first contact structure 132a directly overlies at least one of the trenches in the plurality of trenches 102t. The first contact structure 132a provides a contact region for the third electrode 110 that at least partially directly overlies the plurality of trenches 102t, such that a minimum width and length of the of the capacitor 103 may be reduced while the first contact structure 132a is sufficiently large to facilitate proper formation of the overlying conductive via 138 on the first contact structure 132a. This mitigates potential issues during fabrication of the capacitor 103 as a result of processing tool limitations while increasing a number of semiconductor devices (e.g., capacitors) that may be disposed on/over the semiconductor substrate 102. Thus, a performance (e.g., capacitance density) of the capacitor 103 may be maintained while increasing a device density of the IC 100.

FIG. 1B illustrates a top view of some embodiments of the IC 100 of FIG. 1A taken along line A-A′ of FIG. 1A. For clarity, the etch stop layer (122 of FIG. 1A), the ILD layer (136 of FIG. 1A), and one or more masking layers (e.g., the masking layer 134a of FIG. 1A) are omitted from the top view of FIG. 1B.

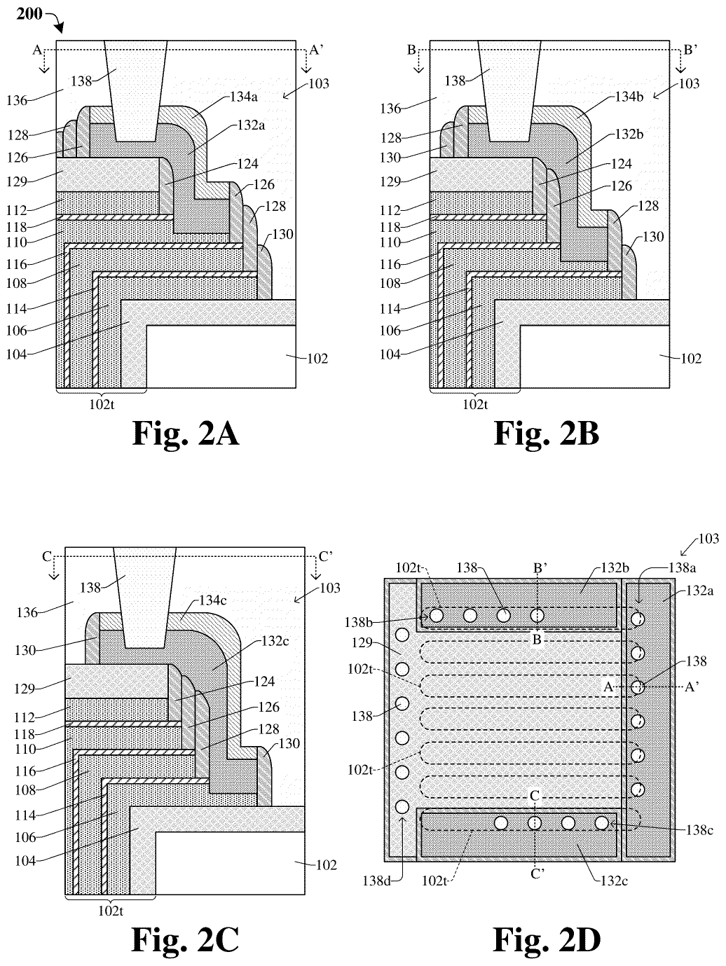

As shown in FIG. 1B, a plurality of contact structures 132a-c overlies the capacitor 103. The plurality of contact structures 132a-c comprises the first contact structure 132a, a second contact structure 132b, and a third contact structure 132c. In some embodiments, the first contact structure 132a, the second contact structure 132b, and the third contact structure 132c respectively directly contact the third electrode (110 of FIG. 1A), the second electrode (108 of FIG. 1A), and the first electrode (106 of FIG. 1A) in regions that are at least partially laterally offset from the plurality of trenches 102t by a non-zero distance in a direction away from a center of the capacitor 103 (e.g., see FIGS. 2A-2D). Further, the first contact structure 132a, the second contact structure 132b, and the third contact structure 132c respectively directly overlie at least a portion of one or more trenches in the plurality of trenches 102t. This, in part, facilitates decreasing a length L and a width W of the capacitor 103 while mitigating issues during fabrication the capacitor 103. Further, the plurality of contact structures 132a-c may, for example, be or comprise titanium, tantalum, titanium nitride, tantalum nitride, tungsten, aluminum, copper, another suitable conductive material, or any combination of the foregoing. In yet further embodiments, the plurality of contact structures 132a-c may each comprise a first conductive layer over a second conductive layer (not shown), where the first conductive layer comprises a first conductive material (e.g., titanium nitride, tantalum nitride, etc.) and the second conductive layer comprises a second conductive material (e.g., tungsten, aluminum copper, etc.) different from the first conductive material.

In some embodiments, the plurality of conductive vias 138 comprises a first subset of conductive vias 138a, a second subset of conductive vias 138b, a third subset of conductive vias 138c, and a fourth subset of conductive vias 138d. Conductive vias 138 in the first subset 138a directly contact the first contact structure 132a and are directly electrically coupled to the third electrode (110 of FIG. 1A) by way of the first contact structure 132a. Conductive vias 138 in the second subset 138b directly contact the second contact structure 132b and are directly electrically coupled to the second electrode (108 of FIG. 1A) by way of the second contact structure 132b. Conductive vias 138 in the third subset 138c directly contact the third contact structure 132c and are directly electrically coupled to the first electrode (106 of FIG. 1A) by way of the third contact structure 132c. Further, conductive vias 138 in the fourth subset 138d directly contact and are directly electrically coupled to the fourth electrode (112 of FIG. 1A). The contact structures 132a-d are configured to shift a conductive via landing region for one or more of the electrodes (e.g., the first, second, and third electrodes 106-110) of the capacitor 103 towards a center of the capacitor 103. This ensures that the conductive via landing region is sufficiently large to accurately form the conductive vias 138 on corresponding electrodes while reducing a lateral footprint of the capacitor 103. Thus, a device density of the IC 100 may be increased while maintaining a performance (e.g., a capacitance density) of the capacitor 103.

FIGS. 2A-2D illustrate various views of some embodiments of an IC 200 corresponding to some alternative embodiments of the IC 100 of FIGS. 1A-B. FIG. 2D illustrates a top view of some embodiments of the IC 200. For clarity, the ILD layer (136 of FIGS. 2A-2C) and one or more masking layers (e.g., masking layers 134a-c of FIGS. 2A-2C) are omitted from the top view of FIG. 2D. FIG. 2A illustrates a cross-sectional view of some embodiments of the IC 200 taken along line A-A′ of the top view of FIG. 2D. FIG. 2B illustrates a cross-sectional view of some embodiments of the IC 200 taken along line B-B′ of the top view of FIG. 2D. FIG. 2C illustrates a cross-sectional view of some embodiments of the IC 200 taken along line C-C′ of the top view of FIG. 2D.

As shown in FIGS. 2A-2D, the semiconductor substrate 102 comprises a plurality of sidewalls defining a plurality of trenches 102t that are laterally offset from one another. The semiconductor substrate 102 may, for example, be or comprise a bulk substrate (e.g., bulk silicon), monocrystalline silicon, a silicon-on-insulator (SOI) substrate, or another suitable substrate. The capacitor 103 comprises a plurality of electrodes 106-112 and a plurality of capacitor dielectric layers 114-118 that overlie the semiconductor substrate 102 and are respectively stacked within the plurality of trenches 102t. An insulator layer 104 is disposed between the semiconductor substrate 102 and the capacitor 103. A capping dielectric layer 129 overlies the plurality of electrodes 106-112 and fills the trenches 102t.

In some embodiments, the plurality of electrodes 106-112 may respectively be or comprise titanium, titanium nitride, tantalum, tantalum nitride, another conductive material, or any combination of the foregoing. In various embodiments, the plurality of electrodes 106-112 respectively comprise a same conductive material such as titanium nitride. The plurality of capacitor dielectric layers 114-118 may, for example, be or comprise a high-k dielectric material such as aluminum oxide, hafnium oxide, zirconium oxide, tantalum oxide, titanium oxide, some other high-k dielectric material(s), another dielectric material, or any combination of the foregoing. The insulator layer 104 may, for example, be or comprise an oxide (e.g., such as silicon dioxide) or another dielectric material. The capping dielectric layer 129 may, for example, be or comprise silicon dioxide, silicon oxynitride, silicon oxycarbide, another dielectric material, or any combination of the foregoing.

In various embodiments, a plurality of contact structures 132a-c and a plurality of masking layers 134a-c overlie the capacitor 103. The plurality of contact structures 132a-c includes a first contact structure 132a, a second contact structure 132b, and a third contact structure 132c. The plurality of masking layers 134a-c includes a first masking layer 134a, a second masking layer 134b, and a third masking layer 134c. In various embodiments, the masking layers 134a-c may, for example, respectively be or comprise silicon dioxide, silicon nitride, silicon carbide, other material(s), or any combination of the foregoing. The first masking layer 134a overlies the first contact structure 132a, the second masking layer 134b overlies the second contact structure 132b, and the third masking layer 134c overlies the third contact structure 132c. The first contact structure 132a directly contacts the third electrode 110, the second contact structure 132b directly contacts the second electrode 108, and the third contact structure 132c direct contacts the first electrode 106.

A plurality of sidewall spacers 124-130 laterally encloses sidewalls of the plurality of electrodes 106-112, sidewalls of the plurality of capacitor dielectric layers 114-118, sidewalls of the plurality of contact structures 132a-c, and sidewalls of the masking layer 134a-c. The plurality of sidewall spacers 124-130 includes a first sidewall spacer 124, a second sidewall spacer 126, a third sidewall spacer 128, and a fourth sidewall spacer 130. In various embodiments, the sidewall spacers 124-130 may, for example, respectively be or comprise silicon dioxide, silicon nitride, silicon carbide, silicon oxycarbide, silicon oxynitride, aluminum oxide, other dielectric material(s), or any combination of the foregoing. The first sidewall spacer 124 laterally encloses sidewalls of the fourth electrode 112. The second sidewall spacer 126 laterally encloses sidewalls of the third electrode 110 and sidewalls of the first contact structure 132a. The third sidewall spacer 128 laterally encloses sidewalls of the second electrode 108 and sidewalls of the second contact structure 132b. The fourth sidewall spacer 130 laterally encloses sidewalls of the first electrode 106 and sidewalls of the third contact structure 132c.

The ILD layer 136 overlies the capacitor 103 and a plurality of conductive vias 138 are disposed within the ILD layer 136. The ILD layer 136 comprises one or more stacked dielectric layers, which may respectively be or comprise an oxide (e.g., silicon dioxide), a low-k dielectric material (a dielectric material with a dielectric constant less than about 3.9), other dielectric material(s), or any combination of the foregoing. The conductive vias 138 may, for example, respectively be or comprise copper, aluminum, tungsten, titanium nitride, tantalum nitride, ruthenium, other conductive material(s), or any combination of the foregoing.

As shown in FIGS. 2A and 2D, the first contact structure 132a directly overlies one or more trenches in the plurality of trenches 102t. Further, the first contact structure 132a continuously extends from along a top surface of the capping dielectric layer 129, along a sidewall of the first sidewall spacer 124 and a sidewall of the third capacitor dielectric layer 118, to an upper surface of the third electrode 110. In some embodiments, the upper surface of the third electrode 110 is vertically offset from a top surface of the third electrode 110 by a non-zero distance. In further embodiments, the first contact structure 132a directly contacts a sidewall of the third electrode 110. In yet further embodiments, an outer sidewall of the first contact structure 132a is aligned with an outer sidewall of the third electrode 110.

As shown in FIGS. 2B and 2D, the second contact structure 132b directly overlies at least one trench in the plurality of trenches 102t. The second contact structure 132b continuously extends from along the top surface of the capping dielectric layer 129, along a sidewall of the second sidewall spacer 126 and a sidewall of the second capacitor dielectric layer 116, to an upper surface of the second electrode 108. In some embodiments, the upper surface of the second electrode 108 is vertically offset from a top surface of the second electrode 108 by a non-zero distance. In further embodiments, the second contact structure 132b directly contacts a sidewall of the second electrode 108. In yet further embodiments, an outer sidewall of the second contact structure 132b is aligned with an outer sidewall of the second electrode 108.

As shown in FIGS. 2C and 2D, the third contact structure 132c directly overlies at least one trench in the plurality of trenches 102t. The third contact structure 132c continuously extends from along the top surface of the capping dielectric layer 129, along a sidewall of the third sidewall spacer 128 and a sidewall of the first capacitor dielectric layer 114, to an upper surface of the first electrode 106. In some embodiments, the upper surface of the first electrode 106 is vertically offset from a top surface of the first electrode 106 by a non-zero distance. In further embodiments, the third contact structure 132c directly contacts a sidewall of the first electrode 106. In yet further embodiments, an outer sidewall of the third contact structure 132c is aligned with an outer sidewall of the first electrode 106.

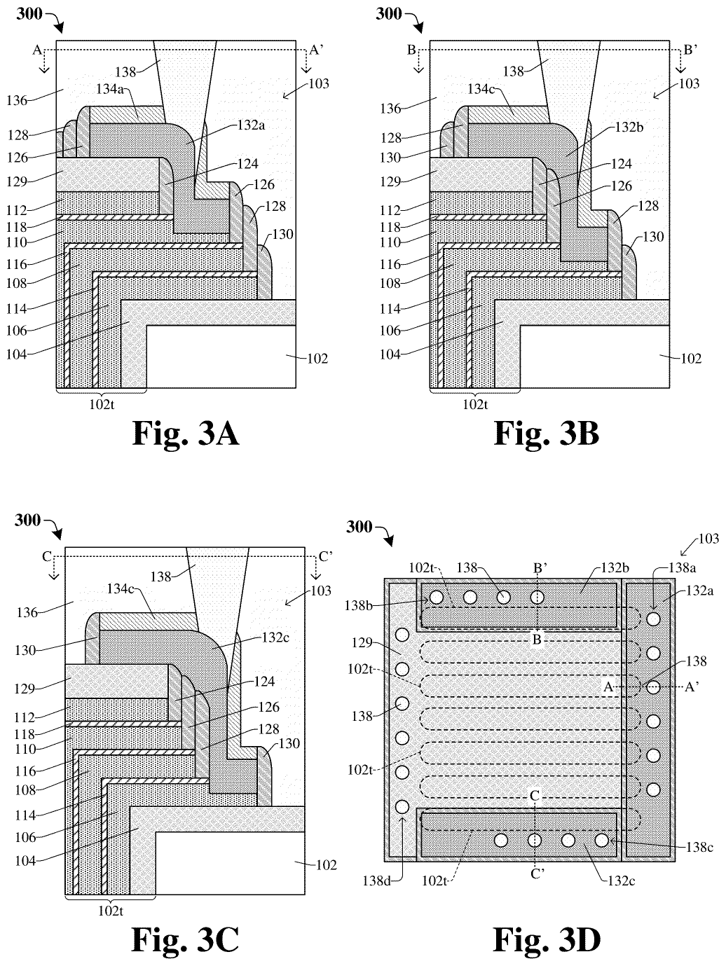

FIGS. 3A-3D illustrate various views of some embodiments of an IC 300 corresponding to some alternative embodiments of the IC 200 of FIGS. 3A-3D, in which the conductive vias 138 respectively contact a sidewall of each contact structure in the plurality of contact structures 132a-c. FIG. 3D illustrates a top view of some embodiments of the IC 300. FIG. 3A illustrates a cross-sectional view of some embodiments of the IC 300 taken along line A-A′ of the top view of FIG. 3D. FIG. 3B illustrates a cross-sectional view of some embodiments of the IC 300 taken along line B-B′ of the top view of FIG. 3D. FIG. 3C illustrates a cross-sectional view of some embodiments of the IC 300 taken along line C-C′ of the top view of FIG. 3D.

It will be appreciated that while the capacitor 103 of FIGS. 1A-1B, 2A-2D, and 3A-3D is represented as a trench capacitor, in various embodiments, the capacitor 103 of FIGS. 1A-1B, 2A-2D, and 3A-3D may be configured as a planar capacitor, a cylinder capacitor, a bar capacitor, a dual-damascene capacitor, or the like.

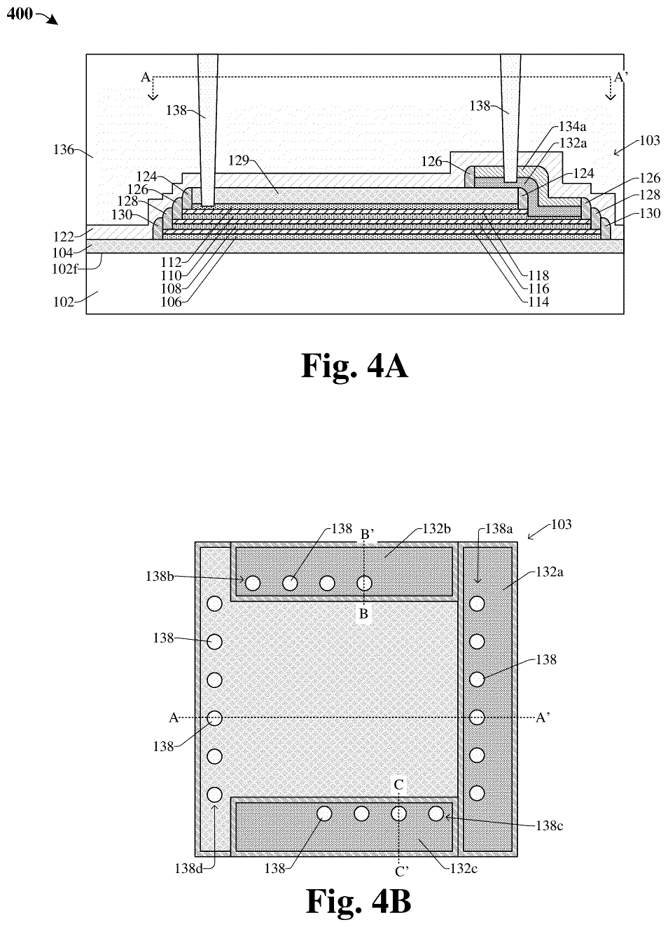

FIGS. 4A-4D illustrate various views of some embodiments of an IC 400 corresponding to some alternative embodiments of the IC 100 of FIGS. 1A-1B, in which the capacitor 103 is configured as a planar capacitor. In such embodiments, the plurality of electrodes 106-112 and the plurality of capacitor dielectric layers 114-118 are each planar and stacked over the semiconductor substrate 102. FIG. 4B illustrates a top view of some embodiments of the IC 400. FIG. 4A illustrates a cross-sectional view of some embodiments of the IC 400 taken along line A-A′ of the top view of FIG. 4B. FIG. 4C illustrates a cross-sectional view of some embodiments of the IC 400 taken along line B-B′ of the top view of FIG. 4B. FIG. 4D illustrates a cross-sectional view of some embodiments of the IC 400 taken along line C-C′ of the top view of FIG. 4B.

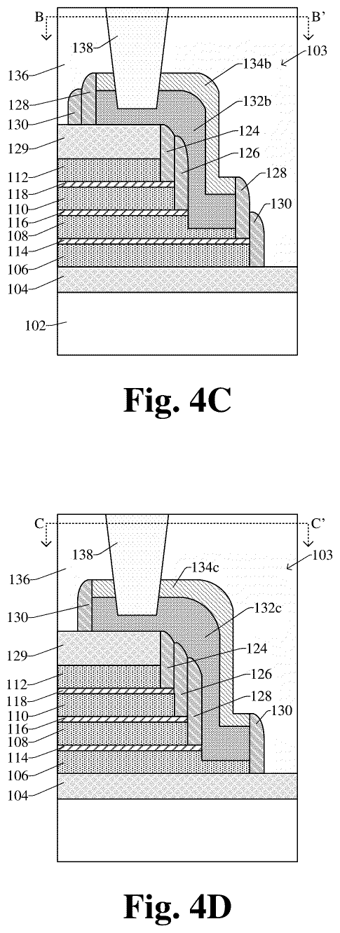

FIGS. 5, 6, and 7A-7C through 14A-14C illustrate various cross-sectional views of some embodiments of a method for forming an integrated circuit (IC) including a capacitor having a plurality of contact structures. With reference to FIG. 2D, figures in this method with a suffix of “A” correspond to a cross-sectional view taken along line A-A′ of FIG. 2D, figures with a suffix of “B” correspond to a cross-sectional view taken along line B-B′ of FIG. 2D, and figures with a suffix of “C” correspond to a cross-sectional view taken along line C-C′ of FIG. 2D. In yet further embodiments, figures with a suffix of “A” are taken along a first edge of a capacitor, figures with a suffix of “B” are taken along a second edge of the capacitor, and figures with a suffix of “C” are taken along a third edge of the capacitor during various formation processes. Although FIGS. 5, 6, and 7A-7C through 14A-14C are described in relation to a series of acts, it will be appreciated that the order of the acts may in some cases be altered and that this series of acts are applicable to structures other than the ones illustrated. In some embodiments, some of these acts may be omitted in whole or in part. Further, it will be appreciated that the structures shown in FIGS. 5, 6, and 7A-7C through 14A-14C are not limited to the method of formation but rather may stand alone as structures separate of the method.

As shown in cross-sectional view 500 of FIG. 5, a patterning process is performed on a semiconductor substrate 102 to form a plurality of trenches 102t extending into a front-side surface 102f of the semiconductor substrate 102. The semiconductor substrate 102 may, for example, be or comprise silicon, a bulk substrate, a silicon-on-insulator (SOI) substrate, some other suitable substrate, or the like. In some embodiments, the patterning process includes: forming a masking layer 502 over the front-side surface 102f of the semiconductor substrate 102; exposing unmasked regions of the semiconductor substrate 102 to one or more etchants; and performing a removal process to remove the masking layer 502 (not shown).

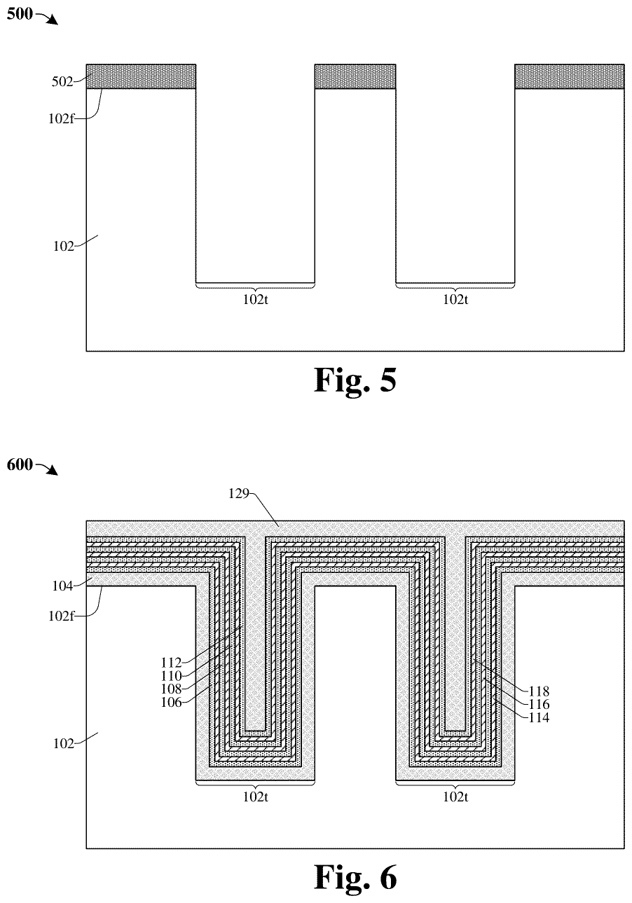

As shown in cross-sectional view 600 of FIG. 6, an insulator layer 104 is formed over the semiconductor substrate 102 and lines the trenches 102t. The insulator layer 104 may, for example, be deposited by chemical vapor deposition (CVD), physical vapor deposition (PVD), atomic layer deposition (ALD), thermal oxidation, or another suitable deposition or growth process. Subsequently, a plurality of electrodes 106-112 and a plurality of capacitor dielectric layers 114-118 are formed over the front-side surface 102f of the semiconductor substrate 102 and within the trenches 102t. Further, a capping dielectric layer 129 is formed over the plurality of electrodes 106-112, thereby filling a remaining of the trenches 102t. In some embodiments, the electrodes 106-112 and the capacitor dielectric layers 114-118 may respectively be formed by ALD, CVD, PVD, sputtering, electroplating, or another suitable deposition or growth process. The plurality of electrodes 106-112 includes a first electrode 106, a second electrode 108, a third electrode 110, and a fourth electrode 112. The plurality of capacitor dielectric layers 114-118 includes a first capacitor dielectric layer 114, a second capacitor dielectric layer 116, and a third capacitor dielectric layer 118.

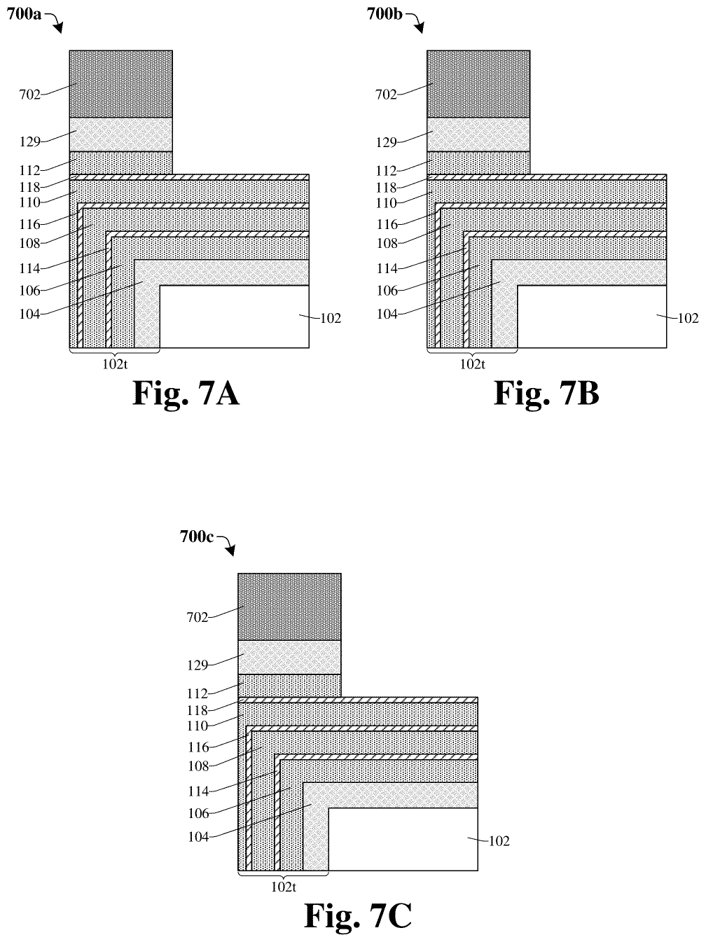

As shown in cross-sectional views 700a-c of FIGS. 7A-7C, an etching process is performed on the fourth electrode 112 and the capping dielectric layer 129 according to an upper masking layer 702. The etching process exposes a surface of the third capacitor dielectric layer 118. The etching process may, for example, include performing a wet etch process, a dry etch process, another suitable etch process, or any combination of the foregoing. In various embodiments, after the etching process, a removal process is performed to remove the upper masking layer 702 (not shown). In some embodiments, the upper masking layer 702 is or comprises a photoresist, a hard mask, or the like.

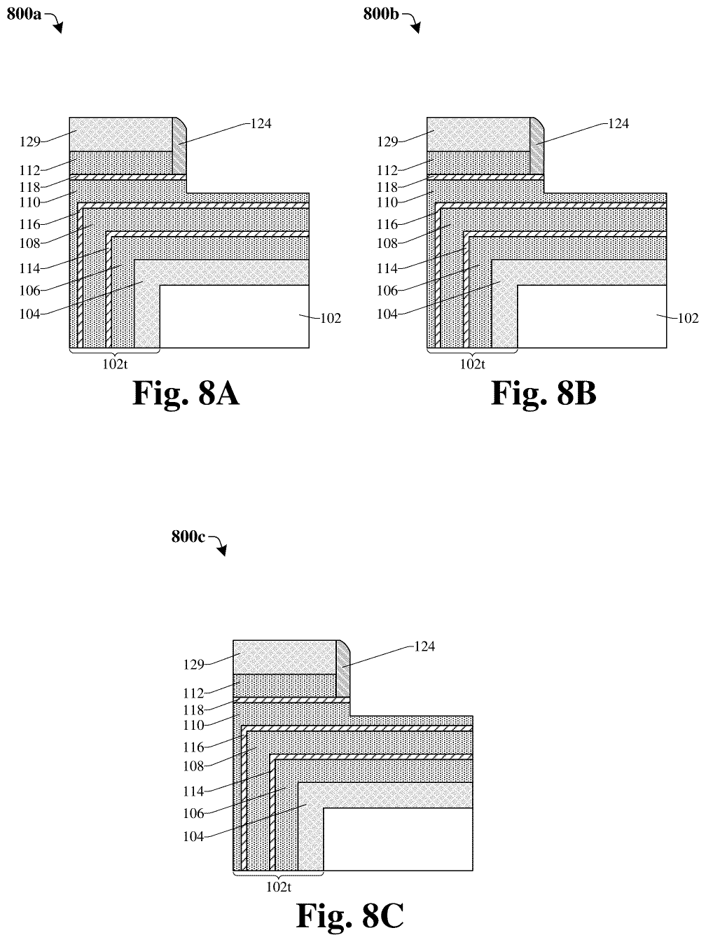

As shown in cross-sectional views 800a-c of FIGS. 8A-8C, a first sidewall spacer 124 is formed along opposing sidewalls of the fourth electrode 112 and sidewalls of the capping dielectric layer 129. In some embodiments, a process for forming the first sidewall spacer 124 includes: depositing (e.g., by CVD, PVD, ALD, etc.) a spacer layer over the semiconductor substrate 102; and performing an etching process (e.g., a wet etch and/or a dry etch) on the spacer layer to remove the spacer layer from horizontal surfaces. In various embodiments, the etching process over-etches into the third capacitor dielectric layer 118 and the third electrode 110. In yet further embodiments, the etching process defines an upper surface of the third electrode 110, which is disposed vertically below a top surface of the third electrode 110 and connected to the top surface of the third electrode 110 through a side surface. In various embodiments, this etching process may be performed to form the first sidewall spacer 124 without an additional masking layer. Portions of the deposited spacer layer covering sidewalls of the capping dielectric layer 129 and covering sidewalls of the fourth electrode 112 may remain, while the upper surface of the capping dielectric layer 129 and the upper surface of the third electrode 110 are exposed by the etching process. Thus, in some embodiments, the first sidewall spacer 124 may be formed without adding a lithography process.

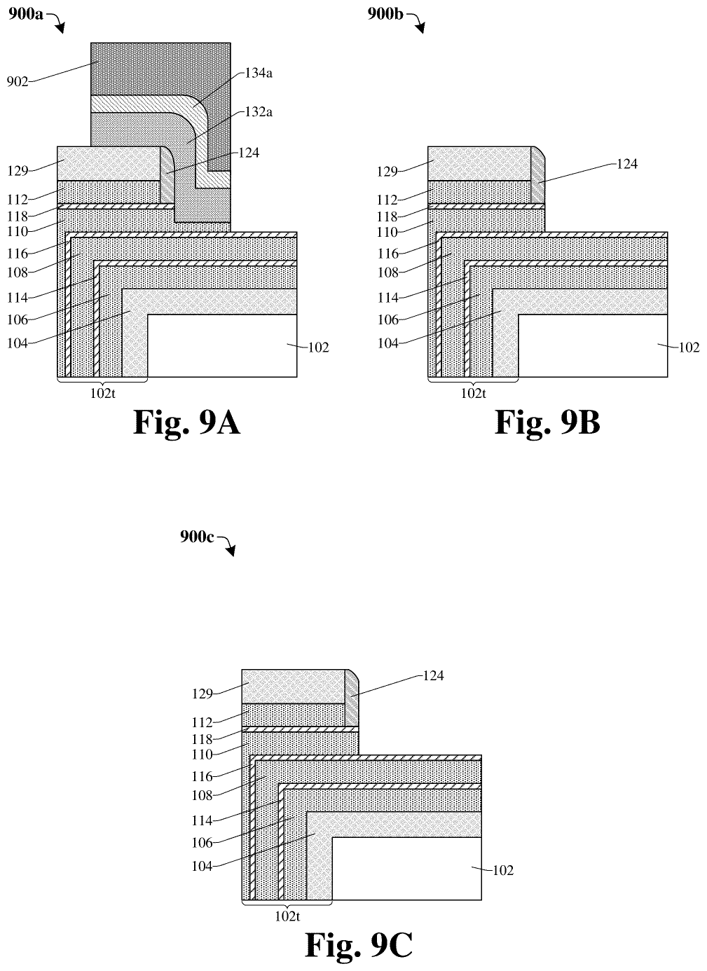

As shown in cross-sectional views 900a-c of FIGS. 9A-9C, a first contact structure 132a is formed over the capping dielectric layer 129 and the third electrode 110. In some embodiments, the first contact structure 132a directly contacts the third electrode 110 and directly overlies at least one trench in the plurality of trenches 102t. In various embodiments, a process for forming the first contact structure 132a includes: depositing (e.g., by CVD, PVD, ALD, sputtering, electroplating, etc.) a metal material over the semiconductor substrate 102; forming a first masking layer 134a over the metal material; forming an upper masking layer 902 over the first masking layer 134a; and performing an etching process (e.g., a dry etch and/or a wet etch) on the metal material to define the first contact structure 132a. In further embodiments, the etching process removes the third electrode 110 from unmasked regions of the semiconductor substrate 102. In addition, a removal process may be performed to remove the upper masking layer 902 from over the first contact structure 132a (not shown).

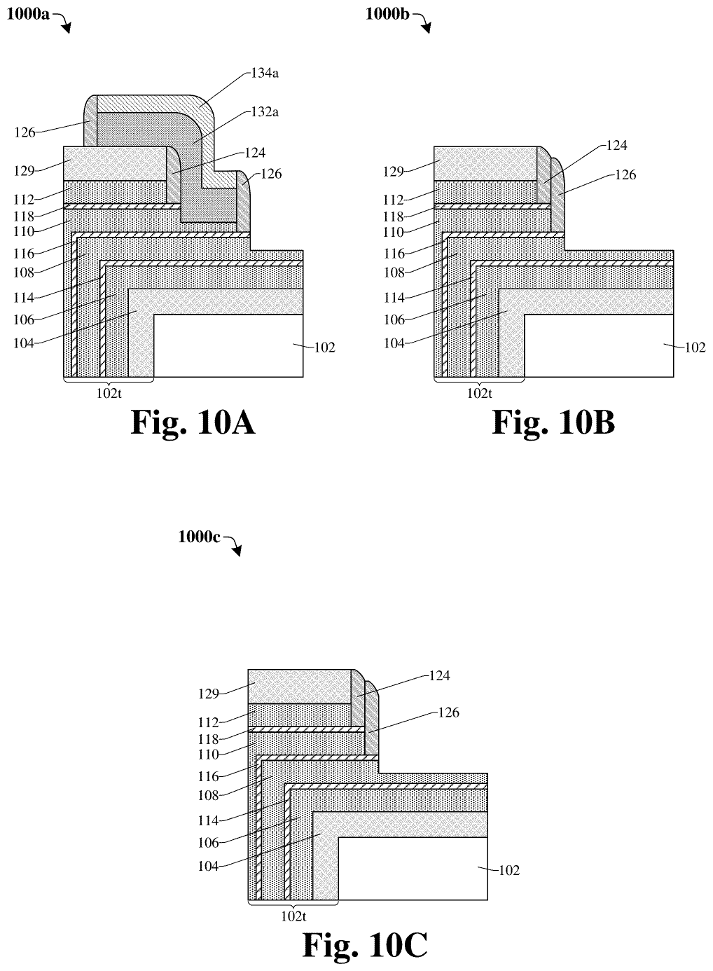

As shown in cross-sectional views 1000a-c of FIGS. 10A-10C, a second sidewall spacer 126 is formed along opposing sidewalls of the third electrode 110 and opposing sidewalls of the first contact structure 132a. In some embodiments, a process for forming the second sidewall spacer 126 includes: depositing (e.g., by CVD, PVD, ALD, etc.) a spacer layer over the semiconductor substrate 102; and performing an etching process (e.g., a wet etch and/or a dry etch) on the spacer layer to remove the spacer layer from horizontal surfaces. In various embodiments, the etching process over-etches into the second capacitor dielectric layer 116 and the second electrode 108. In yet further embodiments, the etching process defines an upper surface of the second electrode 108, which is disposed vertically below a top surface of the second electrode 108 and connected to the top surface of the second electrode 108 through a side surface. In various embodiments, this etching process may be performed to form the second sidewall spacer 126 without an additional masking layer. Portions of the deposited spacer layer covering sidewalls of the third electrode 110, sidewalls of the first contact structure 132a, and sidewalls of the first masking layer 134a may remain, while the upper surface of the capping dielectric layer 129 and the upper surface of the second electrode 108 are exposed by the etching process. Thus, in some embodiments, the second sidewall spacer 126 may be formed without adding a lithography process.

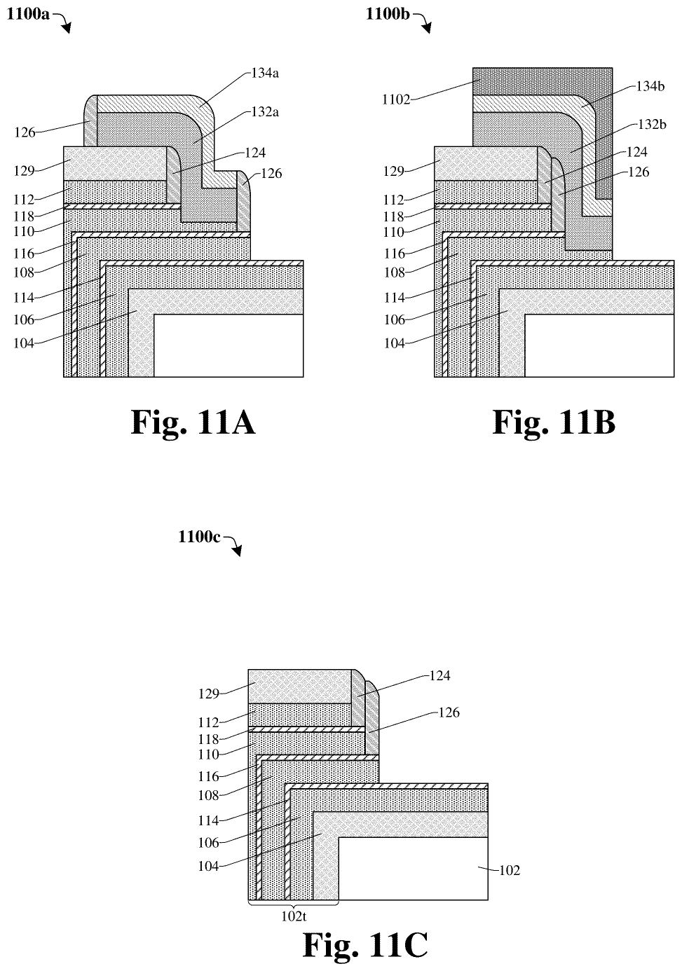

As shown in cross-sectional views 1100a-c of FIGS. 11A-11C, a second contact structure 132b is formed over the capping dielectric layer 129 and the second electrode 108. In some embodiments, the second contact structure 132b directly contacts the second electrode 108 and directly overlies at least one trench in the plurality of trenches 102t. In various embodiments, a process for forming the second contact structure 132b includes: depositing (e.g., by CVD, PVD, ALD, sputtering, electroplating, etc.) a metal material over the semiconductor substrate 102; forming a second masking layer 134b over the metal material; forming an upper masking layer 1102 over the second masking layer 134b; and performing an etching process (e.g., a dry etch and/or a wet etch) on the metal material to define the second contact structure 132b. In further embodiments, the etching process removes the second electrode 108 from unmasked regions of the semiconductor substrate 102. In yet further embodiments, the upper masking layer 1102 may be or comprise a photoresist. In addition, a removal process may be performed to remove the upper masking layer 1102 from over the second contact structure 132b (not shown).

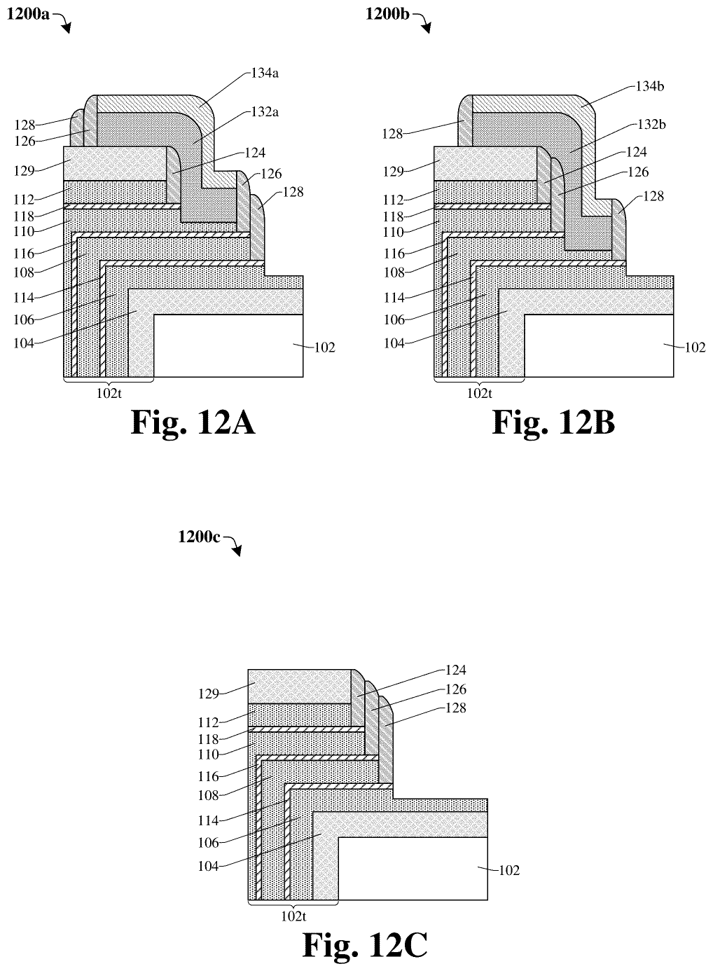

As shown in cross-sectional views 1200a-c of FIGS. 12A-12C, a third sidewall spacer 128 is formed along opposing sidewalls of the second electrode 108 and opposing sidewalls of the second contact structure 132b. In some embodiments, a process for forming the third sidewall spacer 128 includes: depositing (e.g., by CVD, PVD, ALD, etc.) a spacer layer over the semiconductor substrate 102; and performing an etching process (e.g., a wet etch and/or a dry etch) on the spacer layer to remove the spacer layer from horizontal surfaces. In various embodiments, the etching process over-etches into the first capacitor dielectric layer 114 and the first electrode 106. In yet further embodiments, the etching process defines an upper surface of the first electrode 106, which is disposed vertically below a top surface of the first electrode 106 and connected to the top surface of the first electrode 106 through a side surface. In various embodiments, this etching process may be performed to form the third sidewall spacer 128 without an additional masking layer. Portions of the deposited spacer layer covering sidewalls of the second electrode 108, sidewalls of the second contact structure 132b, and sidewalls of the second masking layer 134b may remain, while the upper surface of the capping dielectric layer 129 and the upper surface of the first electrode 106 are exposed by the etching process. Thus, in some embodiments, the third sidewall spacer 128 may be formed without adding a lithography process.

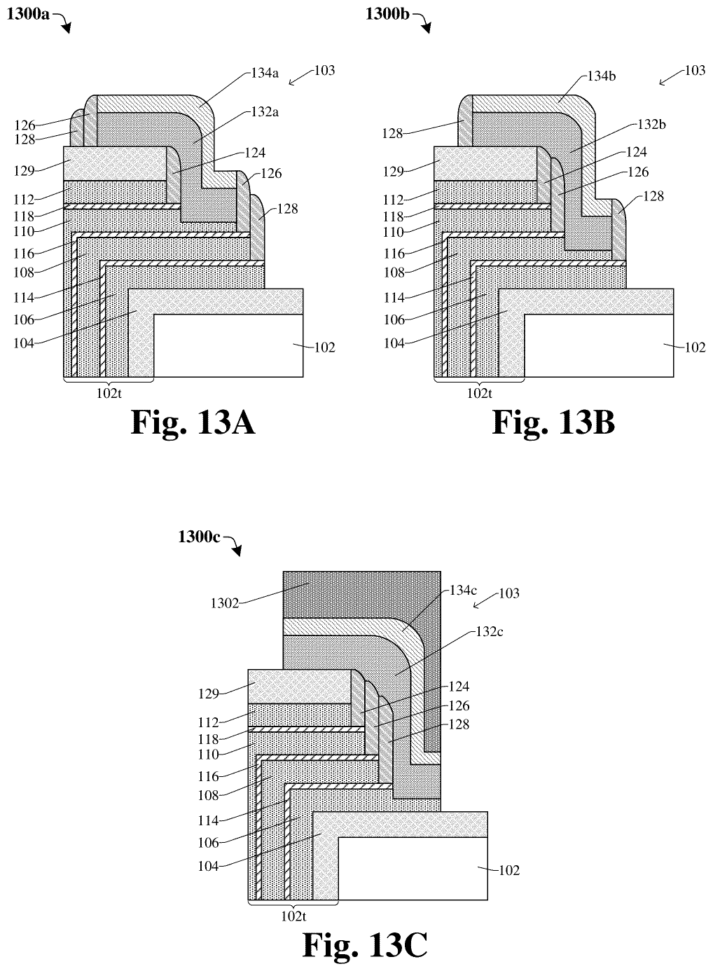

As shown in cross-sectional views 1300a-c of FIGS. 13A-13C, a third contact structure 132c is formed over the capping dielectric layer 129 and the first electrode 106, thereby defining a capacitor 103 in/over the plurality of trenches 102t. In some embodiments, the third contact structure 132c directly contacts the first electrode 106 and directly overlies at least one trench in the plurality of trenches 102t. In various embodiments, a process for forming the third contact structure 132c includes: depositing (e.g., by CVD, PVD, ALD, sputtering, electroplating, etc.) a metal material over the semiconductor substrate 102; forming a third masking layer 134c over the metal material; forming an upper masking layer 1302 over the third masking layer 134c; and performing an etching process (e.g., a dry etch and/or a wet etch) on the metal material to define the third contact structure 132c. In further embodiments, the etching process removes the first electrode 106 from unmasked regions of the semiconductor substrate 102. In yet further embodiments, the upper masking layer 1302 may be or comprise a photoresist. In addition, a removal process may be performed to remove the upper masking layer 1302 from over the third contact structure 132c (not shown).

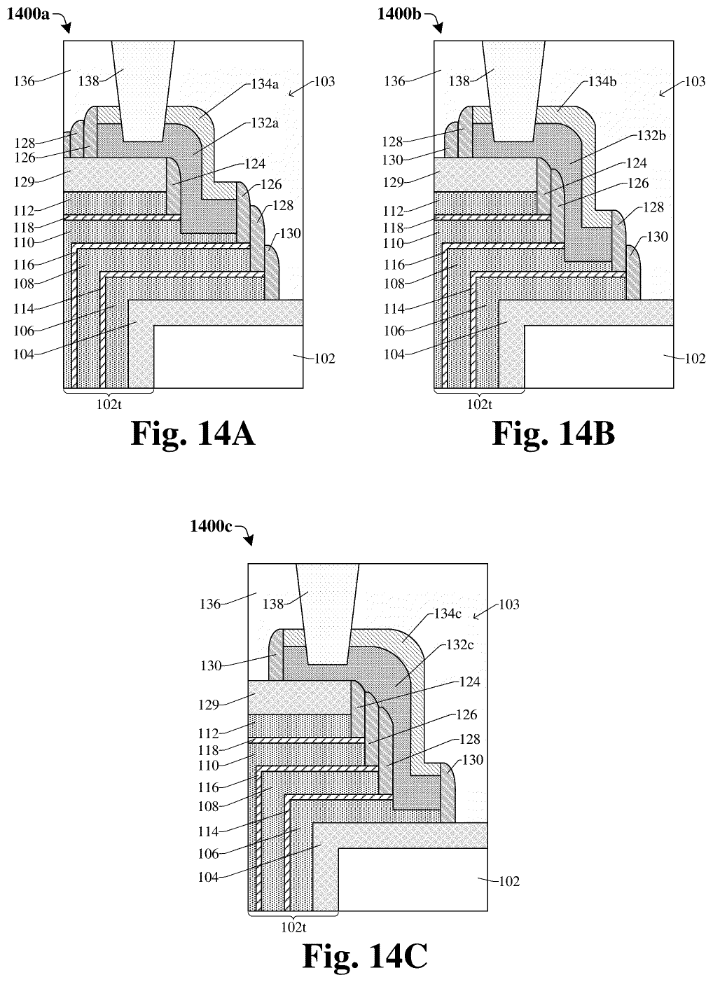

As shown in cross-sectional views 1400a-c of FIGS. 14A-14C, a fourth sidewall spacer 130 is formed along opposing sidewalls of the first electrode 106 and opposing sidewalls of the third contact structure 132c. Further, an interlayer dielectric (ILD) layer 136 is formed over the semiconductor substrate 102 and a plurality of conductive vias 138 is formed within the ILD layer 136. In various embodiments, the plurality of conductive vias 138 are formed directly on the plurality of contact structures 132a-c such that the conductive vias 138 are directly electrically coupled to the first, second, and third electrodes 106-110 by way of the contact structures 132a-c. In yet further embodiments, the conductive vias 138 are formed such that a subset of conductive vias 138 directly contact the fourth electrode 112 along a fourth edge of the capacitor 103 (e.g., see FIGS. 1A-1B). In some embodiments, a process for forming the fourth sidewall spacer 130 includes: depositing (e.g., by CVD, PVD, ALD, etc.) a spacer layer over the semiconductor substrate 102; and performing an etching process (e.g., a wet etch and/or a dry etch) on the spacer layer to remove the spacer layer from horizontal surfaces. The ILD layer 136 may, for example, be deposited by CVD, PVD, ALD, or another suitable growth or deposition process.

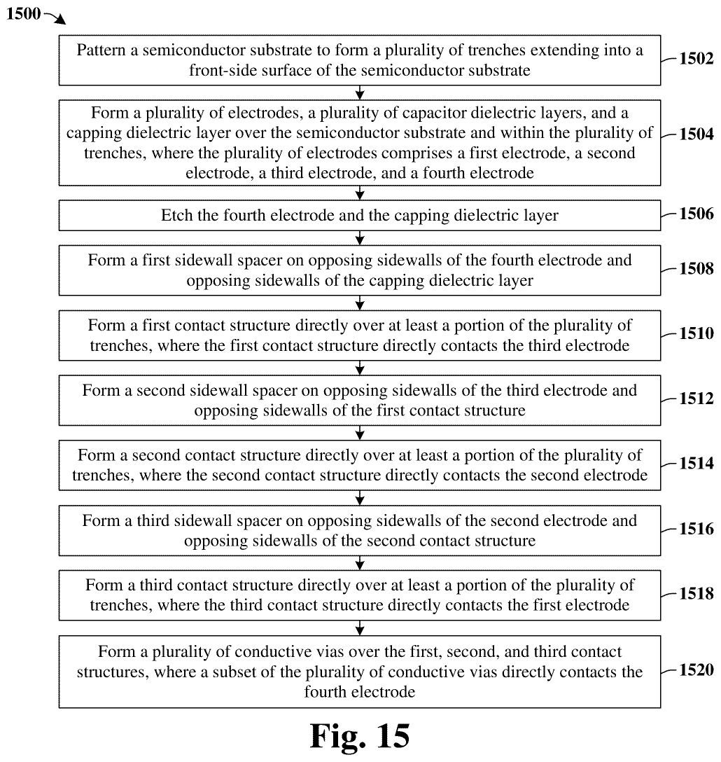

FIG. 15 illustrates a method 1500 of forming an integrated circuit (IC) including a capacitor having a plurality of contact structures according to the present disclosure. Although the method 1500 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1502, a semiconductor substrate is patterned to form a plurality of trenches extending into a front-side surface of the semiconductor substrate. FIG. 5 illustrates a cross-sectional view 500 of some embodiments corresponding to act 1502.

At act 1504, a plurality of electrodes, a plurality of capacitor dielectric layers, and a capping dielectric layer are formed over the semiconductor substrate and within the plurality of trenches. The plurality of electrodes comprises a first electrode, a second electrode, a third electrode, and a fourth electrode. FIG. 6 illustrates a cross-sectional view 600 of some embodiments corresponding to act 1504.

At act 1506, the fourth electrode and the capping dielectric layer are etched. FIGS. 7A-7C illustrate cross-sectional views 700a-c of some embodiments corresponding to act 1506.

At act 1508, a first sidewall spacer is formed on opposing sidewalls of the fourth electrode and opposing sidewalls of the capping dielectric layer. FIGS. 8A-8C illustrate cross-sectional views 800a-c of some embodiments corresponding to act 1508.

At act 1510, a first contact structure is formed directly over at least a portion of the plurality of trenches, where the first contact structure directly contacts the third electrode. FIGS. 9A-9C illustrate cross-sectional views 900a-c of some embodiments corresponding to act 1510.

At act 1512, a second sidewall spacer is formed on opposing sidewalls of the third electrode and opposing sidewalls of the first contact structure. FIGS. 10A-10C illustrate cross-sectional views 1000a-c of some embodiments corresponding to act 1512.

At act 1514, a second contact structure is formed directly over at least a portion of the plurality of trenches, where the second contact structure directly contacts the second electrode. FIGS. 11A-11C illustrate cross-sectional views 1100a-c of some embodiments corresponding to act 1514.

At act 1516, a third sidewall spacer is formed on opposing sidewalls of the second electrode and opposing sidewalls of the second contact structure. FIGS. 12A-12C illustrate cross-sectional views 1200a-c of some embodiments corresponding to act 1516.

At act 1518, a third contact structure is formed directly over at least a portion of the plurality of trenches, where the third contact structure directly contacts the first electrode. FIGS. 13A-13C illustrate cross-sectional views 1300a-c of some embodiments corresponding to act 1518.

At act 1520, a plurality of conductive vias is formed over the first, second, and third contact structures, where a subset of the plurality of conductive vias directly contacts the fourth electrode. FIGS. 14A-14C illustrate cross-sectional views 1400a-c of some embodiments corresponding to act 1520.

Accordingly, in some embodiments, the present disclosure relates to capacitor including a plurality of electrodes disposed within a plurality of trenches. A plurality of contact structures directly overlies at least a portion of the plurality of trenches and directly contact a corresponding electrode in the plurality of electrodes.

In some embodiments, the present application provides an integrated circuit (IC) including a semiconductor substrate; a capacitor disposed over the semiconductor substrate, wherein the capacitor comprises a plurality of electrodes and a plurality of capacitor dielectric layers vertically stacked over one another; a contact structure overlying the plurality of electrodes, wherein the contact structure continuously extends from above a top surface of the plurality of electrodes to contact a first electrode in the plurality of electrodes; and a first conductive via overlying and contacting the contact structure, wherein the first conductive via is directly electrically coupled to the first electrode by way of the contact structure.

In some embodiments, the present application provides an integrated circuit (IC) including a semiconductor substrate; a capacitor comprising a plurality of capacitor dielectric layers and a plurality of electrodes stacked over the semiconductor substrate, wherein the plurality of electrodes comprises a first electrode overlying a second electrode; a first sidewall spacer disposed on opposing sidewalls of the first electrode; and a first contact structure continuously extending from above a top surface of the first electrode, along the first sidewall spacer, to directly contact an upper surface of the second electrode.

In some embodiments, the present application provides a method for forming a capacitor, the method including forming a plurality of electrodes and a plurality of capacitor dielectric layers over a semiconductor substrate, wherein the plurality of electrodes comprises a first electrode overlying a second electrode; and forming a first contact structure over the plurality of electrodes, wherein the first contact structure continuously extends from above the plurality of electrodes to directly contact an upper surface of the second electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) comprising:
a semiconductor substrate;
a capacitor disposed over the semiconductor substrate, wherein the capacitor comprises a plurality of electrodes and a plurality of capacitor dielectric layers vertically stacked over one another;
a contact structure overlying the plurality of electrodes, wherein the contact structure continuously extends from above a top surface of the plurality of electrodes to contact a first electrode in the plurality of electrodes; and
a first conductive via overlying and contacting the contact structure, wherein the first conductive via is directly electrically coupled to the first electrode by way of the contact structure.

2. The IC of claim 1, further comprising:
a second conductive via overlying and contacting a topmost electrode in the plurality of electrodes.

3. The IC of claim 2, wherein a bottom surface of the first conductive via is vertically above a bottom surface of the second conductive via.

4. The IC of claim 1, wherein the semiconductor substrate comprises sidewalls that define a trench, wherein the capacitor is disposed within the trench, and wherein an inner region of the contact structure overlies the trench.

5. The IC of claim 4, wherein a height of the contact structure discretely decreases from the inner region in a direction away from the trench.

6. The IC of claim 4, wherein the first conductive via overlies at least a portion of the trench.

7. The IC of claim 1, wherein an outer sidewall of the contact structure is aligned with an outer sidewall of the first electrode.

8. The IC of claim 1, wherein the contact structure has a curved upper surface.

9. An integrated circuit (IC) comprising:
a semiconductor substrate;
a capacitor comprising a plurality of capacitor dielectric layers and a plurality of electrodes stacked over the semiconductor substrate, wherein the plurality of electrodes comprises a first electrode overlying a second electrode;
a first sidewall spacer disposed on opposing sidewalls of the first electrode; and
a first contact structure continuously extending from above a top surface of the first electrode, along the first sidewall spacer, to directly contact an upper surface of the second electrode.

10. The IC of claim 9, further comprising:
a second contact structure continuously extending from above the top surface of the first electrode to directly contact an upper surface of a third electrode in the plurality of electrodes, wherein a height of the second contact structure is greater than a height of the first contact structure.

11. The IC of claim 10, wherein a sidewall of the first contact structure is adjacent to a sidewall of the second contact structure.

12. The IC of claim 10, wherein a maximum length of the first contact structure is greater than a maximum length of the second contact structure.

13. The IC of claim 10, wherein a bottom surface of the first contact structure is disposed vertically above a bottom surface of the second contact structure.

14. The IC of claim 9, further comprising:
a masking layer over the first contact structure, wherein opposing sidewalls of the masking layer are aligned with opposing sidewalls of the first contact structure.

15. The IC of claim 9, wherein an outer sidewall of the first sidewall spacer is aligned with a sidewall of the second electrode, wherein the first contact structure directly contacts the sidewall of the second electrode.

16. A method for forming a capacitor, the method comprising:
forming a plurality of electrodes and a plurality of capacitor dielectric layers over a semiconductor substrate, wherein the plurality of electrodes comprises a first electrode overlying a second electrode; and
forming a first contact structure over the plurality of electrodes, wherein the first contact structure continuously extends from above the plurality of electrodes to directly contact an upper surface of the second electrode.

17. The method of claim 16, further comprising:
forming a first sidewall spacer along opposing sidewalls of the first electrode, wherein forming the first sidewall spacer comprises depositing a spacer layer over the semiconductor substrate and performing a patterning process on the spacer layer, wherein the patterning process defines the upper surface of the second electrode.

18. The method of claim 16, further comprising:
forming a second sidewall spacer along opposing sidewalls of the first contact structure and opposing sidewalls of the second electrode, wherein forming the second sidewall spacer comprises depositing a spacer layer over the semiconductor substrate and performing a patterning process on the spacer layer, wherein the patterning process etches a third electrode under the second electrode and defines an upper surface of the third electrode.

19. The method of claim 18, further comprising:
forming a second contact structure over the plurality of electrodes, wherein the second contact structure directly contacts the upper surface of the third electrode.

20. The method of claim 16, further comprising:
forming a plurality of conductive vias over the plurality of electrodes, wherein a first subset of the conductive vias directly contact the first contact structure and a second subset of the conductive vias directly contact the first electrode.
